(19) United States
(12) Patent Application Publication
(10) Pub. No.: US 2024/0194461 A1
(43) Pub. Date: Jun. 13, 2024

(54) PLASMA PROCESSING METHOD

(71) Applicant: HITACHI HIGH-TECH CORPORATION, Minato-ku, Tokyo (JP)

(72) Inventors: Kenta TAMARU, Tokyo (JP); Takanori NAKATSUKA, Tokyo (JP); Yuta TAKAGI, Tokyo (JP); Tatsuya HAYASHI, Tokyo (JP)

(21) Appl. No.: 17/909,491

(22) PCT Filed: Jul. 14, 2021
(86) PCT No.: PCT/JP2021/026386

§ 371 Date: Sep. 6, 2022

(51) Int. Cl. H01J 37/32

(52) U.S. Cl. CPC H01J 37/32862; H01J 37/32174; H01J 2237/334

(57) ABSTRACT

Provided is a plasma processing method capable of suppressing the diffusion of contamination to a transportation system while forming a deposited film on the inner wall of a processing chamber. The plasma processing method, in which a sample placed on a sample table is plasma-processed in a processing chamber, includes: a first step of removing deposits in the processing chamber by using plasma; a second step of depositing the deposits in the processing chamber by using a mixed gas of hydrofluorocarbon gas and argon (Ar) gas after the first step; a third step of selectively removing the deposits on the sample table by using a mixed gas of oxygen (O₂) gas and argon (Ar) gas after the second step; and a fourth step of plasma-processing a predetermined number of sheets of the sample after the third step.

### TECHNICAL FIELD

The present invention relates to a plasma processing method.

### BACKGROUND ART

In recent years, the miniaturization in semiconductor manufacturing, such as in integrated circuits, has been progressing, and the requirements for etching products have become more stringent. In particular, foreign matter and contamination on wafers significantly reduce the yield rate. For this reason, development of technologies to reduce foreign matter and contamination is in progress. Particularly, when the cause of foreign matter and contamination is in the components in the processing chamber, the formation of a deposited film on the components in the processing chamber is effective in reducing the foreign matter and contamination.

Patent Document 1 proposes a processing method including a first step of removing a residual film in the processing chamber by plasma of oxygen gas and a second step of forming a deposited film on the inner wall of the processing chamber by using plasma of carbon fluoride gas or mixed gas containing the carbon fluoride gas. According to this processing method, the formed deposited film prevents the generation of foreign matter by suppressing the degradation of the internal parts of the processing chamber that occurs during plasma etching, thereby preventing pattern defects caused by the adhesion of foreign matter on the product wafer.

### CITATION LIST

### Patent Documents

Patent Document 1: Japanese Patent Application Laid-Open No. 2000-091327

### SUMMARY OF THE INVENTION

### Problem to be Solved by the Invention

When the processing method disclosed in Patent Document 1 is performed without placing a wafer on the mounting table, however, there is a problem that a deposited film is also formed on the mounting table. If the deposited film is formed on the mounting table, the deposited film may adhere to the backside of the processed wafer when the wafer is placed on the mounting table for etching processing. The deposited film adhering to the processed wafer may separate from and drop off the processed wafer and become foreign matter during transportation of the deposited film together with the processed wafer, and then may diffuse through a transportation robot or the like, thereby resulting in the contamination of the entire transportation system.

On the other hand, it can be said that, if it is merely required to prevent the formation of a deposited film on the mounting table, a dummy wafer may be placed on the mounting table during performing the processing method disclosed in Patent Document 1, and then removed after processing. Although this method is able to prevent the formation of a deposited film on the mounting table, the method is not able to prevent the formation of a deposited film on the dummy wafer. Therefore, there is still a risk that the deposited film on the dummy wafer will separate from and drop off the dummy wafer during the transportation of the deposited film together with the dummy wafer and will become foreign matter, thereby contaminating the transportation system.

The present invention provides a plasma processing method capable of suppressing the diffusion of contamination to the transportation system while forming a deposited film on the inner wall of the processing chamber.

### Means for Solving the Problems

To achieve the above object, as one of the typical plasma processing methods according to the present invention, there is provided a plasma processing method, in which a sample placed on a sample table is plasma-processed in a processing chamber, the method including: a first step of removing deposits in the processing chamber by using plasma; a second step of depositing the deposits in the processing chamber by using a mixed gas of hydrofluorocarbon gas and argon (Ar) gas after the first step; a third step of selectively removing the deposits on the sample table by using a mixed gas of oxygen (O₂) gas and argon (Ar) gas after the second step; and a fourth step of plasma-processing a predetermined number of sheets of the sample after the third step.

### Advantageous Effect of the Invention

The present invention provides a plasma processing method capable of suppressing the diffusion of contamination to the transportation system while forming a deposited film on the inner wall of the processing chamber.

Problems, configurations, and advantageous effects other than those described above are clarified in the following description of the embodiments.

### BRIEF DESCRIPTION OF THE DRAWINGS

FIG. 1 is a cross-sectional view schematically illustrating a plasma processing device according to an embodiment of the present invention.

FIG. 2 is a flowchart illustrating an example of a plasma processing method using the plasma processing device illustrated in FIG. 1.

FIG. 3 is a diagram schematically illustrating a state of the plasma processing for forming a deposited CHx film by using a mixed gas containing methyl fluoride (CH₃F) and argon (Ar).

FIG. 4 is a diagram schematically illustrating a state of the plasma processing for removing a deposited film by using a mixed gas containing oxygen (O₂) and argon (Ar).

FIG. 5 is a diagram illustrating a comparison of etching rates for a deposited film of carbon compounds with and without bias in plasma processing and a comparison of etching rates for the deposited film with various current values of solenoid coils.

### MODES FOR CARRYING OUT THE INVENTION

Specific examples of the plasma processing method according to the embodiment of the present invention are described below with reference to the drawings.

### (Plasm Processing Device)

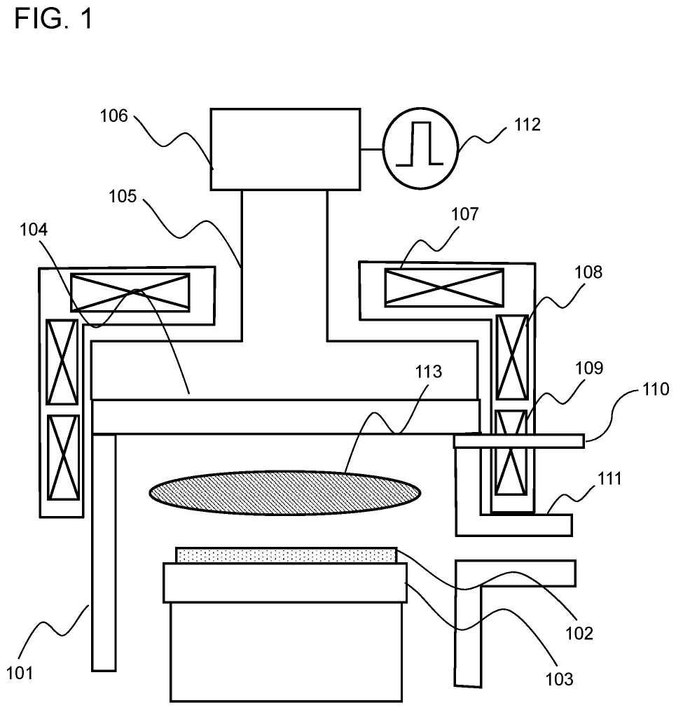

First, an example of a plasma etching device for implementing the plasma processing method of this embodiment is described with reference to FIG. 1. FIG. 1 is a schematic diagram of an electron cyclotron resonance (hereinafter, referred to as “ECR”) type plasma etching device, which utilizes microwaves and magnetic fields as a plasma generation means.

The ECR type plasma etching device includes a processing chamber 101, the inside of which is able to be evacuated, a mounting table 103 on which a wafer 102, which is a sample, is placed inside the processing chamber 101, and a microwave transmission window 104 made of quartz and provided on the top surface of the processing chamber 101, a waveguide 105 provided above the microwave transmission window 104, a magnetron (microwave generator) 106 that emits microwaves, a first radio-frequency power supply 112 that supplies radio-frequency power to the magnetron 106, solenoid coils 107, 108, 109 (magnetic field generators) arranged along the axial direction around the processing chamber 101, and a gas supply pipe 110 for introducing process gas into the processing chamber 101.

The first radio-frequency power supply 112 has a function of pulse-modulating the microwaves to be emitted.

During the plasma etching processing, the wafer 102 is brought into the processing chamber 101 from the wafer loading port 111 via a transportation robot or the like, and is then electrostatically adsorbed onto the mounting table 103 by an electrostatic adsorption power supply (not illustrated).

Subsequently, the process gas is introduced into the processing chamber 101 from the gas supply pipe 110. The inside of the processing chamber 101 is depressurized and evacuated by a vacuum pump (not illustrated), and the pressure is adjusted to a predetermined level (for example, 0.1 Pa to 50 Pa).

Then, upon the supply of the predetermined radio-frequency power to the magnetron 106 from the first radio-frequency power supply 112, microwaves with a frequency of 2.45 GHz are emitted from the magnetron 106, and these microwaves propagate through the waveguide 105 and are supplied into the processing chamber 101.

The process gas is excited by the interaction between the microwaves and the magnetic field generated by the solenoid coils 107, 108, and 109, and plasma 113 is generated in the space above the wafer 102.

On the other hand, bias power is applied to the mounting table 103 by a second radio-frequency power supply (not illustrated), and the ions in the plasma 113 are vertically accelerated and injected onto the wafer 102. In addition, the second radio-frequency power supply (not illustrated) is able to apply continuous bias power or time-modulated bias power to the mounting table 103. This causes the wafer 102 to be etched anisotropically by the action of radicals and ions from the plasma 113.

The values of the currents supplied to the solenoid coils 107, 108, and 109 are able to be controlled. Therefore, the region where ECR is generated are able to be changed in the vertical direction by the respective current values.

### (Plasma Processing Method)

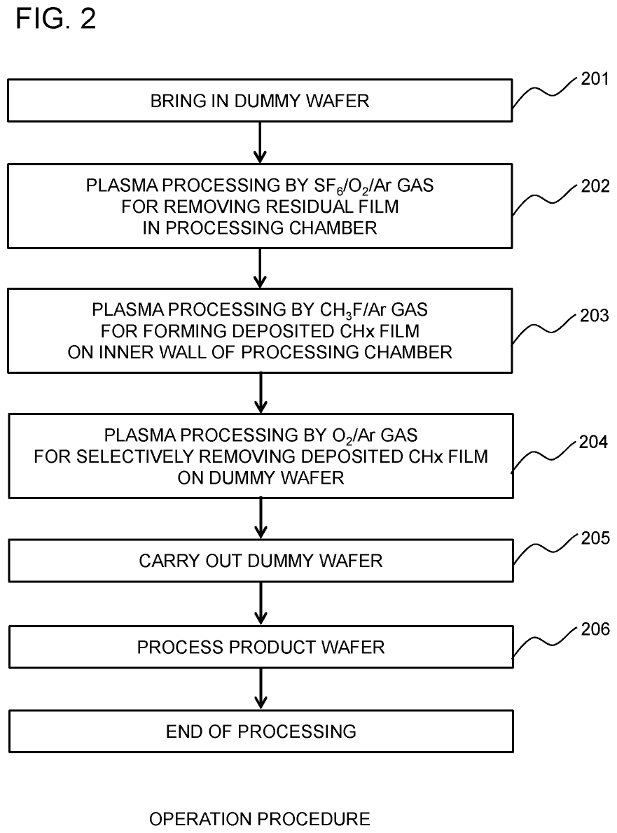

Subsequently, the plasma processing method using the plasma etching device illustrated in FIG. 1 is described with reference to the drawings. FIG. 2 is a flowchart of the plasma processing method according to the embodiment of the present invention.

In this specification, a gas containing carbon, hydrogen, and fluorine is referred to as “CHF-based gas.”

In step 201, a dummy wafer (dummy sample), which is brought in from the wafer loading port 111 via the transportation robot or the like, is placed on the mounting table 103 in order to prevent a deposited film from being formed on the mounting table 103.

After the dummy wafer is placed, a mixed gas containing sulfur hexafluoride (SF₆), oxygen (O₂), and argon (Ar) is supplied from the gas supply pipe 110 into the processing chamber 101 to perform plasma processing in step 202 (first step), thereby removing the residual film (deposits) in the processing chamber 101.

As the conditions for the above plasma processing, SF₆, O₂, and Ar are supplied at 150 mL/min, at 27 mL/min, and at 60 mL/min, respectively, the processing chamber pressure is 0.6 Pa, microwave power is 1000 W, and the values of the currents to the solenoid coils 107, 108, and 109 in the upper part are set to 27, 26, and 0 A, respectively, and the processing time is 60 sec.

In step 203 (the second step), the mixed gas containing methyl fluoride (CH₃F) and argon (Ar) is supplied from the gas supply pipe 110 into the processing chamber 101 to perform plasma processing, thereby forming a deposited CHx film on the inner wall of the processing chamber.

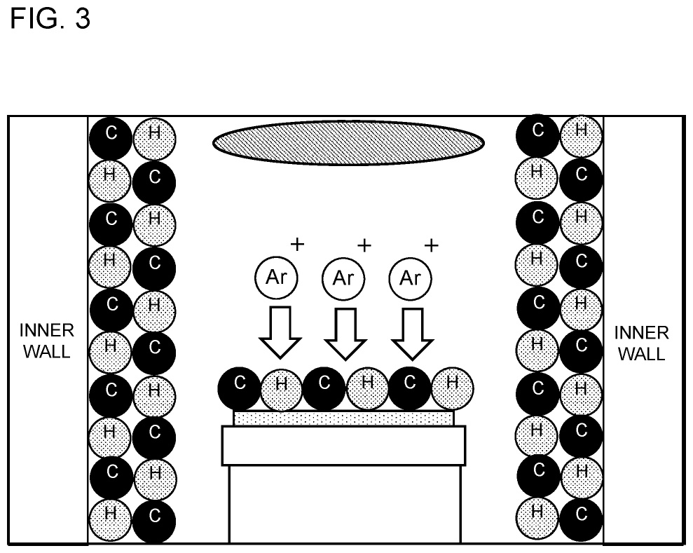

FIG. 3 is a schematic diagram illustrating a state in which a deposited CHx film is formed on the inner wall of the processing chamber. The plasma processing in step 203 is performed by applying bias power (radio-frequency power) to the mounting table 103, so that the deposited film on the dummy wafer is not deposited so much, compared to the deposited film on the inner wall of the processing chamber, by ion sputtering. In other words, the deposit amount on the dummy wafer is able to be suppressed by performing both of deposition and etching on the dummy wafer by the plasma processing in step 203.

As the conditions for the above plasma processing, CH₃F and Ar are supplied at 100 mL/min and at 100 mL/min, respectively, the processing chamber pressure is 0.5 Pa, microwave power is 800 W, bias power is 50 W, the values of the currents to the solenoid coils 107, 108, and 109 are set to 27, 26, and 0 A, respectively, and the processing time is 160 sec. In this embodiment, the methyl fluoride (CH₃F) gas was used, but hydrofluorocarbon gases such as difluoromethane (CH₂F₂) gas and trifluoromethane (CHF₃) gas may also be used instead of to the methyl fluoride (CH₃F) gas.

In step 204 (the third step), while supplying radio-frequency power to the mounting table 103, the mixed gas containing oxygen (O₂) and argon (Ar) is supplied from the gas supply pipe 110 into the processing chamber 101 to perform plasma processing, thereby selectively removing the deposited CHx film formed in step 203 on the dummy wafer placed in step 201.

After plasma processing in step 204, the dummy wafer placed on the mounting table 103 is carried out via a transportation robot or the like in step 205. Then, in step 206 (the fourth step), a predetermined number of product wafers are plasma-processed. This enables the processing of product wafers to be implemented while suppressing foreign matter contamination.

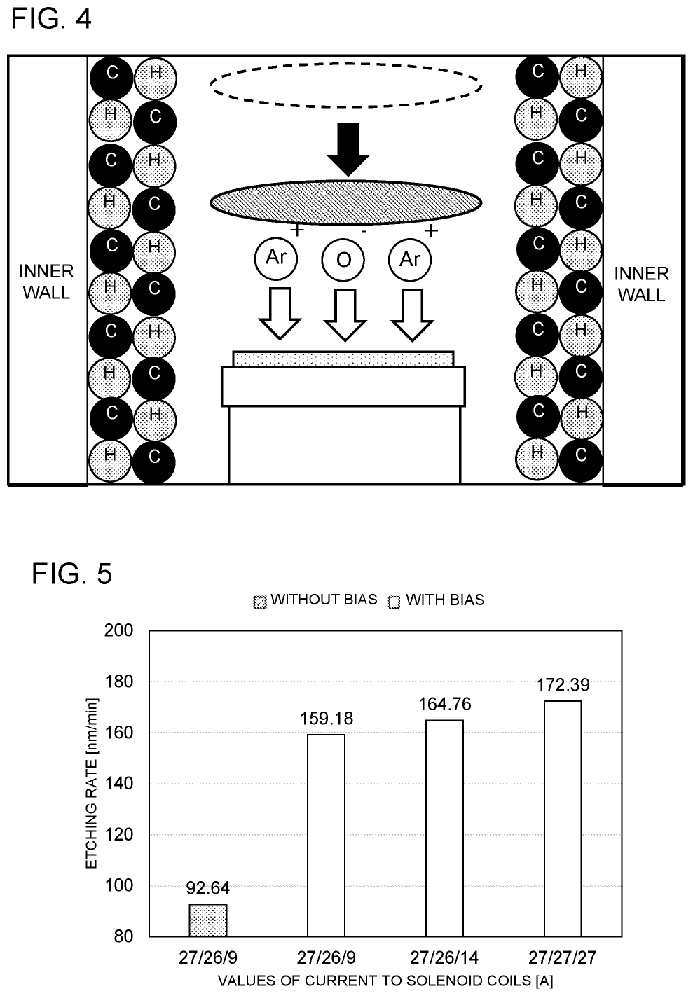

FIG. 4 is a diagram illustrating the state of deposited CHx film removal on the dummy wafer. The plasma processing in step 204 is performed by applying bias power to the mounting table 103, thereby suppressing the removal of the deposited film on the inner wall of the processing chamber, while selectively removing the deposited film on the dummy wafer.

As the conditions for the above plasma processing, O₂ and Ar are supplied at 30 mL/min and at 150 mL/min, respectively, the processing chamber pressure is 0.5 Pa, microwave power is 400 W, bias power is 50 W, and the values of the currents to the solenoid coils 107, 108, and 109 are set to 27, 26, and 9 A, respectively, and the processing time is 230 sec.

FIG. 5 is a diagram illustrating a comparison of etching rates for a deposited film of carbon compounds at the processing in step 204, when the current value of the solenoid coil is changed in the case where no bias power is applied to the mounting table 103 (without bias) and the case where bias power is applied (with bias). Specifically, the values of the currents to the solenoid coils 107, 108, and 109 are set to 27, 26, and 9 A for both with and without bias, and further the values of the currents to the solenoid coils 107, 108, and 109 are changed to 27, 26, and 14 A and to 27, 27, and 27 A, respectively, for with bias, and the etching rates are obtained.

When the values of the currents to the solenoid coils 107, 108, and 109 are common, the etching rate without bias is 92.64 nm/min, while the etching rate with bias is 159.18 nm/min, indicating that the etching progresses more in the case with bias. Therefore, the deposited film on the wafer is able to be selectively removed by applying bias power.

If the etching rates are compared in the case where the current values to the solenoid coils 107, 108, and 109 are varied, the etching rate is 159.18 nm/min in the case where the current values are 27, 26, and 9 A, respectively, 164.76 nm/min in the case where the current values are 27, 26, and 14 A, respectively, and 172.39 nm/min in the case where the current values are 27, 27, 27 A, respectively, thus indicating that the etching rate increases as the current values are increased.

Note here that, as the current value to the solenoid coil 109 increases, the area where plasma is generated in step 204 is closer to the mounting table 103, and therefore more deposited film is able to be removed. In other words, changing the current value to the solenoid coil 109 enables the deposit amount and etching amount of the deposited film in step 204 to be adjusted arbitrarily.

According to this embodiment, the deposited film formed on the mounting table is selectively removed while maintaining the deposited film formed on the inner wall of the processing chamber, thereby preventing the generation of foreign matter while protecting the components inside the processing chamber. This prevents contamination of the transportation system that may be caused by the deposited film formed on the mounting table. In addition, the cost of a dummy wafer is able to be reduced since the dummy wafer is able to be reused by removing the deposited film on the dummy wafer.

### MODIFICATION

The present invention is able to be implemented even in the case where the dummy wafer is not placed on the mounting table (in other words, without steps 201 and 205 in FIG. 4). More specifically, in the case where the dummy wafer is not placed on the mounting table, the deposited CHx film deposited on the mounting table in step 203 is able to be selectively removed in step 204. The amount of CHx deposited on the mounting table is balanced with the etching amount depending on the conditions of plasma processing, thereby enabling the amount of CHx deposited just before the product wafer is placed on the mounting table to be reduced to zero.

This embodiment has been described in detail in order to describe the present invention in an easy-to-understand manner, and the invention is not necessarily limited to the embodiment having all the described configurations.

### DESCRIPTION OF REFERENCE NUMERALS

101 processing chamber
102 wafer
103 mounting table
104 microwave transmission window
105 waveguide
106 magnetron
107, 108, 109 solenoid coil
110 gas supply pipe
111 wafer loading port
112 first radio-frequency power supply

1. A plasma processing method, in which a sample placed on a sample table is plasma-processed in a processing chamber, the method comprising:
a first step of removing deposits in the processing chamber by using plasma;
a second step of depositing the deposits in the processing chamber by using a mixed gas of hydrofluorocarbon gas and argon (Ar) gas after the first step;
a third step of selectively removing the deposits on the sample table by using a mixed gas of oxygen (O₂) gas and argon (Ar) gas after the second step; and
a fourth step of plasma-processing a predetermined number of sheets of the sample after the third step.

2. The plasma processing method according to claim 1, wherein the dummy sample is placed on the sample table in the third step.

3. The plasma processing method according to claim 2, wherein the hydrofluorocarbon gas is methyl fluoride (CH₃F) gas.

4. The plasma processing method according to claim 3, wherein radio-frequency power is supplied to the sample table in the second step.

5. The plasma processing method according to claim 3, wherein radio-frequency power is supplied to the sample table in the third step.

6. The plasma processing method according to claim 4, wherein radio-frequency power is supplied to the sample table in the third step.

7. The plasma processing method according to claim 6, wherein the plasma of the first step is generated by using a mixed gas of argon (Ar) gas, sulfur hexafluoride (SF₆) gas, and oxygen (O₂) gas.
